(19) United States
(12) Patent Application Publication
(10) Pub. No.: US 2025/0298932 A1
(43) Pub. Date: Sep. 25, 2025

(54) SYSTEM AND METHOD FOR CONTROLLING ELAPSED TIME DURING A COMPUTER SIMULATION OF A COMPUTER MODEL

(71) Applicant: Disney Enterprises, Inc., Burbank, CA (US)

(72) Inventors: Richard GRGIC, Concord Township, OH (US); Brian Foster WALTERS, Groveland, FL (US); Tameka MCKENZIE, Clermont, FL (US); Gabrielle STONEY, Orlando, FL (US); Brian FEENY, Winter Garden, FL (US); Michael S. WELCH, Orlando, FL (US)

(73) Assignee: Disney Enterprises, Inc., Burbank, CA (US)

(21) Appl. No.: 18/611,686

(22) Filed: Mar. 20, 2024

(51) Int. Cl. G06F 30/17

(52) U.S. Cl. CPC G06F 30/17

(57) ABSTRACT

A simulation platform may execute a computer model to cause a set of devices to perform different sets of tasks during different steps, of a simulation, to simulate operations of the set of devices. The set of devices may include one or more physical devices and one or more simulated devices. The simulation platform may determine, during a step of the simulation, that the set of devices have not completed a set of tasks that are to be completed. The simulation platform may cause the simulated controller to suspend time elapsed during the simulation based on determining that the set of devices have not performed the set of tasks. The simulation platform may determine, during the step of the simulation, that the set of devices have completed the set of tasks and cause the simulated controller to resume time.

### BACKGROUND

A computer model may include mathematical equations that describe a real-world system. The computer model may be in the form of a computer program. The computer program may be executed, by a computer, to cause a computer simulation to be performed. The computer simulation may simulate operations of the components of the system. Accordingly, the computer simulation may be used to evaluate the components.

### SUMMARY

A method, performed by a scheduler of a simulation platform, may comprise: receiving a request to perform a simulation of operations of a plurality of devices; executing, based on the request, a computer model to perform the simulation of the operations of the plurality of devices, executing the computer model includes causing simulated devices, representing the plurality of devices, to perform different sets of tasks during different steps of the simulation to simulate the operations of the plurality of devices; determining, during a step of the simulation, that the simulated devices have not completed a set of tasks that are to be completed during the step of the simulation; causing a simulated controller associated with the simulation to suspend time during the step of the simulation based on determining that the simulated devices have not completed the set of tasks; determining, during the step of the simulation, that the simulated devices have completed the set of tasks after causing the simulated controller to suspend time; and causing the simulated controller to resume time based on determining that the simulated devices have performed the set of tasks.

A system may comprise a simulated controller to control elapsed time during simulations; and a simulation platform to: execute a computer model to cause a set of devices to perform different sets of tasks during different steps, of a simulation, to simulate operations of the set of devices, the set of devices including one or more physical devices and one or more simulated devices; determine, during a step of the simulation, that the set of devices have not completed a set of tasks that are to be completed; cause the simulated controller to suspend time elapsed during the simulation based on determining that the set of devices have not performed the set of tasks; determine, during the step of the simulation, that the set of devices have completed the set of tasks after causing the simulated controller to suspend time; and cause the simulated controller to resume time based on determining that the set of devices have completed the set of tasks.

A device may comprise: one or more processors configured to: execute a computer model to cause a set of devices to perform different sets of tasks during different steps of a simulation to simulate operations of the set of devices; determine, during a step of the simulation, that the set of devices have not completed a set of tasks that are to be completed during a step of the simulation; cause a simulated controller to suspend time elapsed during the simulation based on determining that the simulated devices have not completed the set of tasks; determine, during the step of the simulation, that the simulated devices have completed the set of tasks after causing the simulated controller to suspend time; and cause the simulated controller to resume time based on determining that the simulated devices have performed the set of tasks.

### BRIEF DESCRIPTION OF THE DRAWINGS

FIGS. 1A-1F are diagrams of an example implementation described herein.

FIG. 2 is a diagram of example components of one or more devices of FIG. 1.

FIG. 3 is a flowchart of an example process for controlling time during a simulation.

### DETAILED DESCRIPTION

The following detailed description of example implementations refers to the accompanying drawings. The same reference numbers in different drawings may identify the same or similar elements.

A computer simulation may include a step-by-step process in which a computer program is to use to model operations of a real-world system that includes multiple components. The real-world system may include a baggage handling system (e.g., of an airport). The components may include a controller that control operations of other components of the real-world system. The computer program may be executed, on a computing device, to cause the computer simulation to be performed. As a result of executing the computer program, simulated components (e.g., models of the components of the real-world system) may be generated.

During a step of the computer simulation, each simulated component may perform mathematical computations that cause the simulated component to simulate an operation that is performed during the step. By completing the mathematical computations during the step, the computer simulation may reflect the real-word system being in a state. The simulated components may perform additional mathematical computations during subsequent steps, thereby causing the computer simulation to reflect the real-world system being in subsequent states.

During the computer simulation, the simulated controller may cause time to continuously advance as the computer simulation continuously advances from one step to another step. For example, a first step may occur at a first time, a second step may occur at a second time, and so on. Typically, the simulated controller may cause time to advance based on input from a system clock of the computing device that executes the computer program. In other words, the computing device may provide information identifying the time to the simulated controller (e.g., a system controller may provide an indication of time to the simulated controller).

The simulated controller may cause time to continuously advance by one unit of time (e.g., one second). In some situations, the simulated components may complete the mathematical computations for a current step of the computer simulation during an amount of time that exceeds the one unit of time. For example, the simulated components may be able to logically represent the physical devices in real-time. In this regard, the simulated controller may advance time and the computer simulation may be advanced to a subsequent step before the mathematical computations are completed. The amount of time for completing the mathematical computations may depend on a level of complexity of the real-world system, a computing capability of the computing device, and/or computing resources that are used to perform the mathematical computations.

In this regard, a simulated component may take a longer amount of time to simulate an operation in a simulation environment than a corresponding component to perform the same operation in a real-world environment. Simulated time may elapse during the computer simulation in a manner different than a manner in which actual time elapses in the real-world environment. For example, a speed of a simulated clock in the computer simulation may be different than a speed of an actual clock in the real-world environment (e.g., a speed of a system clock of the computing device executing the computer model). For instance, one second during the computer simulation may be five minutes in the real-world environment (e.g., in computer time).

Time offsets may be introduced during the computer simulation as a result of advancing time and advancing the computer simulation a subsequent step before the mathematical computations is completed for the current step. Initially, the time offsets may cause minor discrepancies during the computer simulation. However, over a period of time, an accumulation of the minor discrepancies may cause the computer simulation to be in an invalid state. In some situations, troubleshooting may be performed on the computer program to determine a cause of the invalid state. Performing troubleshooting in this manner may consume computing resources, storage resources, and/or network resources.

Accordingly, a need exists for a computation simulation that takes into account an amount of time during which mathematical computations are performed by simulated components representing components of a real-world system. The mathematical computations may be performed for different steps of the computer simulation. In this regard, a technical problem discussed herein is controlling a manner in which time advances (or elapses) during a computer simulation.

Implementations described herein are directed to a technical solution that includes controlling time, during a computer simulation, based on information provided by simulated devices and/or physical devices that are part of the computer simulation (hereinafter “simulation). For example, time (e.g., simulated time) may be controlled based on determining whether the simulated devices and/or the physical devices have completed mathematical computations that are to be performed during a step of the simulation. Time may be controlled by suspending time and resuming time (e.g., suspending a simulated clock and resuming the simulated clock). Additionally, or alternatively, time may be controlled by causing the simulated clock to operate at a speed that exceeds a speed of a real-world clock (e.g., a system clock of a computing device hosting the simulation).

As an example, a computer model (in the form of a computer program) may be executed to initialize a simulation. In some examples, the computer model may model a real-world system, such as a luggage handling system. As a result of executing the computer model, simulated devices may be generated. The simulated devices may include models representing different devices included in the real-world system. Additionally, a simulated controller may be generated. The simulated controller may include a model representing a controller (of the real-word system) that controls operations of the devices. The computer program may include a scheduler that manages operations of the simulated devices and the simulated controller.

During a step of the simulation, the simulated devices may perform mathematical computations that cause the simulated devices to simulate an operation of the real-world system that is performed during the step. The scheduler may determine whether the simulated devices have completed the mathematical computations. If the scheduler determines that one or more of the simulated devices have not completed the mathematical computations, the scheduler may provide an instruction to the simulated controller to suspend time (e.g., to suspend a simulated clock of the simulation). The scheduler may cause the simulated controller to continue to suspend time until the scheduler determine that the simulated devices have performed the mathematical computations.

If the scheduler determines that the simulated devices have completed the mathematical computations, the scheduler may provide an instruction to the simulated controller to resume time (e.g., to resume the simulated clock of the simulation). Accordingly, the simulated clock may cause the simulated clock to advance by one unit of time and the simulation may advance to a subsequent step. In this regard, the scheduler may cause the simulated clock to wait until the simulated devices have completed the mathematical computations before enabling time to elapse by one unit of time and enabling the simulation to advance to the subsequent step. The computer program may be developed (or modified) to include code that enables the simulated devices to control the simulated clock instead of the simulated clock being controlled by the simulated controller based on a system clock (e.g., a clock of the computing device).

By waiting until the simulated devices have completed the mathematical computations, implementations described herein provide an advantage of preventing the simulation from being in an invalid state. Additionally, or alternatively, by waiting until the simulated devices have completed the mathematical computations, implementations described herein provide an advantage of preventing the simulation from outputting incorrect information (e.g., incorrect results). Additionally, or alternatively, implementations described herein may provide an advantage of preserving computing resources, storage resources, and/or network resources that would have been used to perform troubleshooting on the computer program.

One advantage of the system described herein is that the system is automated and does not rely solely on human expertise. Another advantage of the system described herein is that the system continuously measures and analyzes the process to visually identify candidate delay factors that cause a delay. For example, the system may constantly learn, in real time (or near real time), causes of the delay in the process and may alert the operator in real time (or near real time) to cause the operator to take corrective actions. An additional advantage of the system described herein is that the system may determine correlations between delays and candidate delay factors. For at least the foregoing, reasons, implementations described herein are an improvement over existing methods of performing a simulation.

While the example described herein may be provided in the context of a luggage handling system (e.g., at an airport), implementations described are applicable to other real-world systems, such as a manufacturing system, a medical facilities system, a ride system and/or of a show system, among other examples. While the example described herein may be provided in the context of reducing a speed of the simulated clock, implementations described are applicable to increasing the speed of the simulated clock. For example, if the mathematical computations are completed expeditiously, the speed of the simulated clock may be increased to exceed the speed of a real-world clock. In this regard, the simulation may be completed within an amount of time that is less than an amount of time during which the operations of the real-world system are completed.

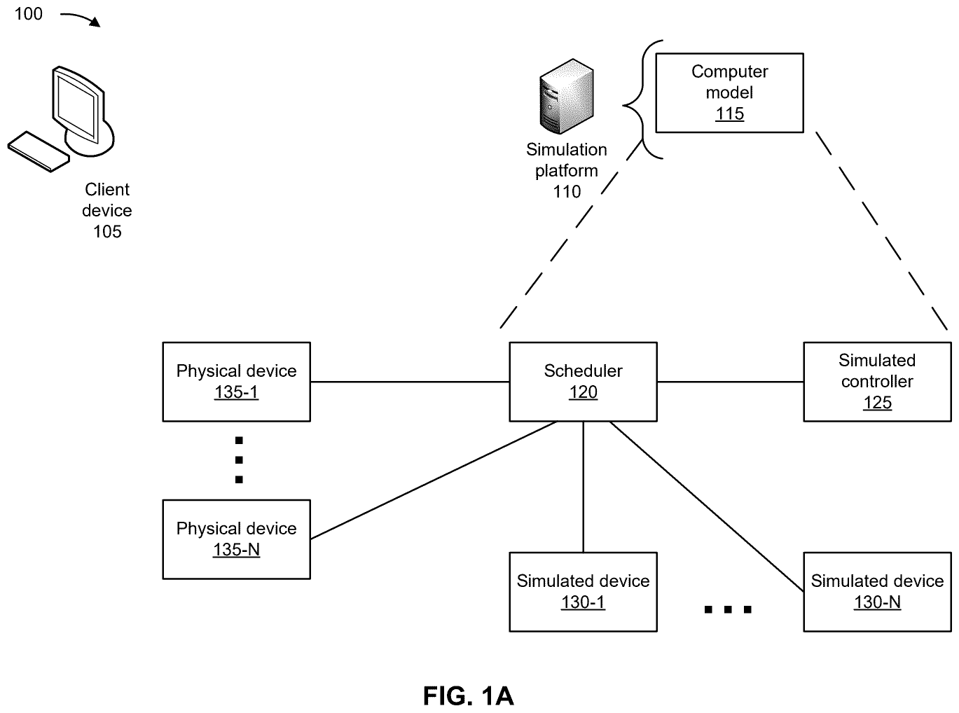

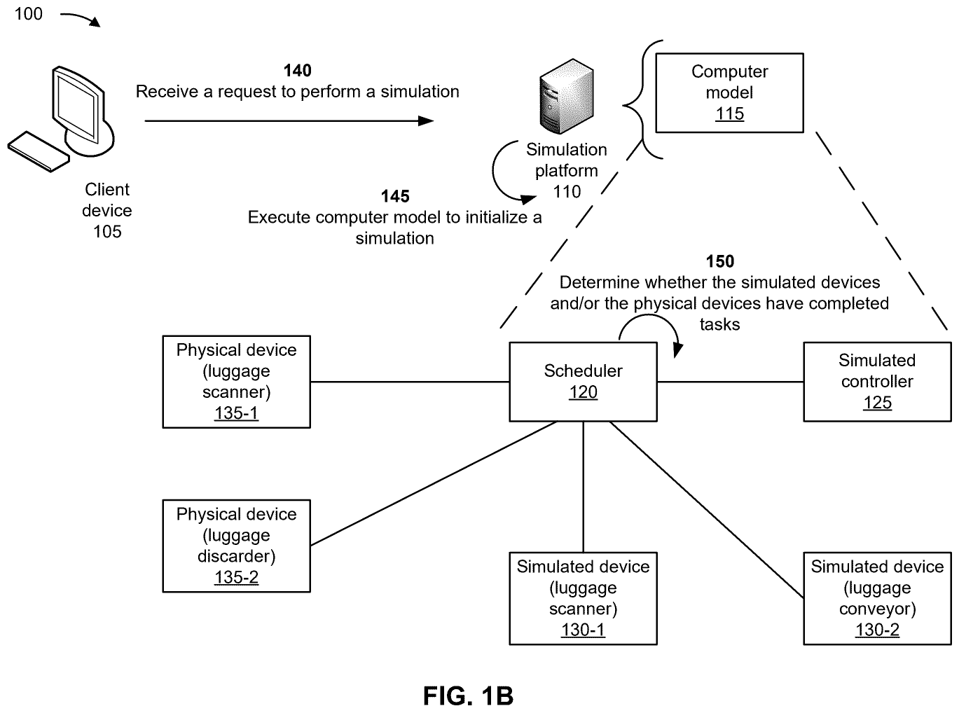

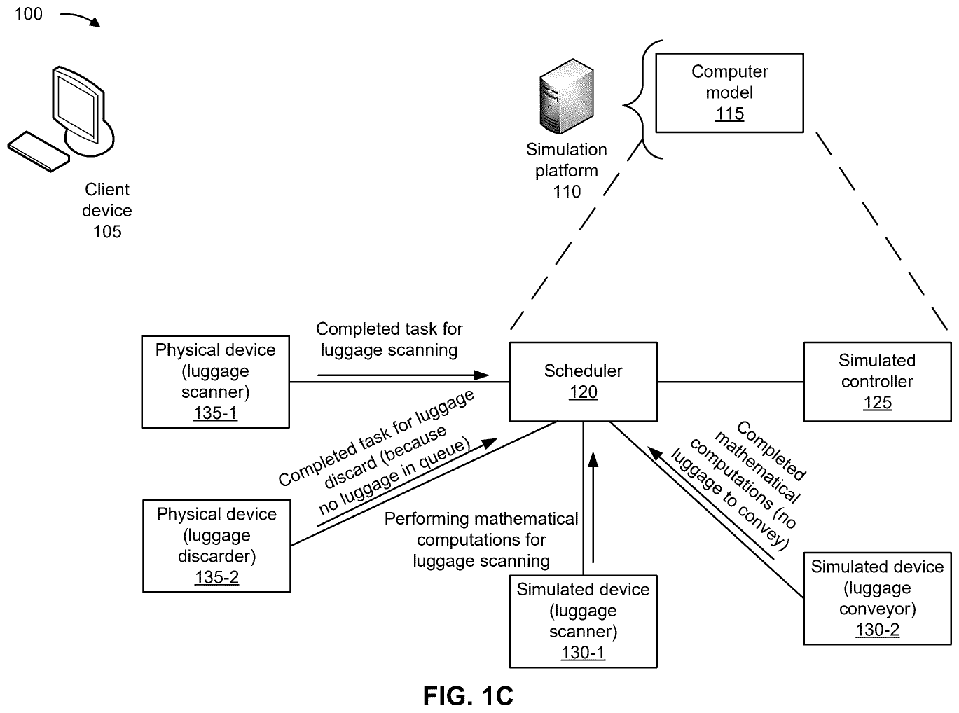

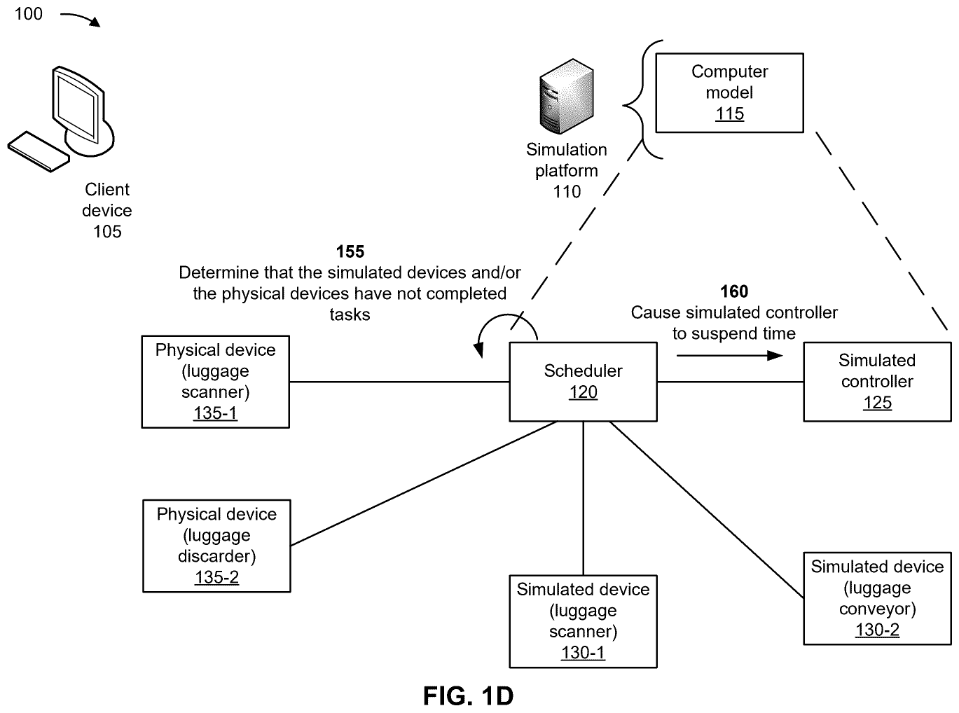

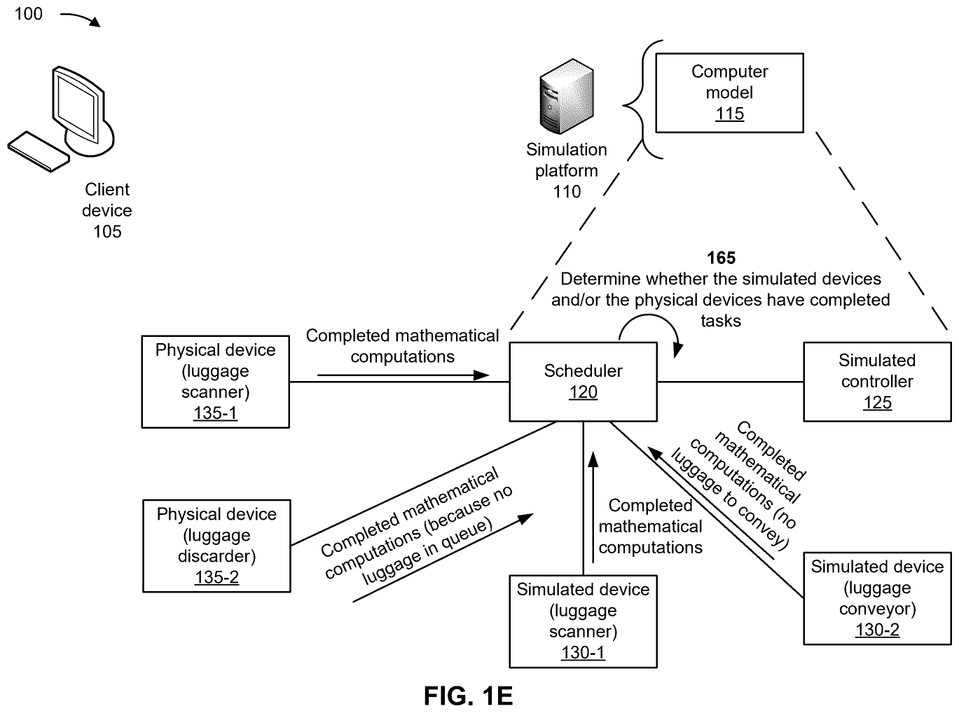

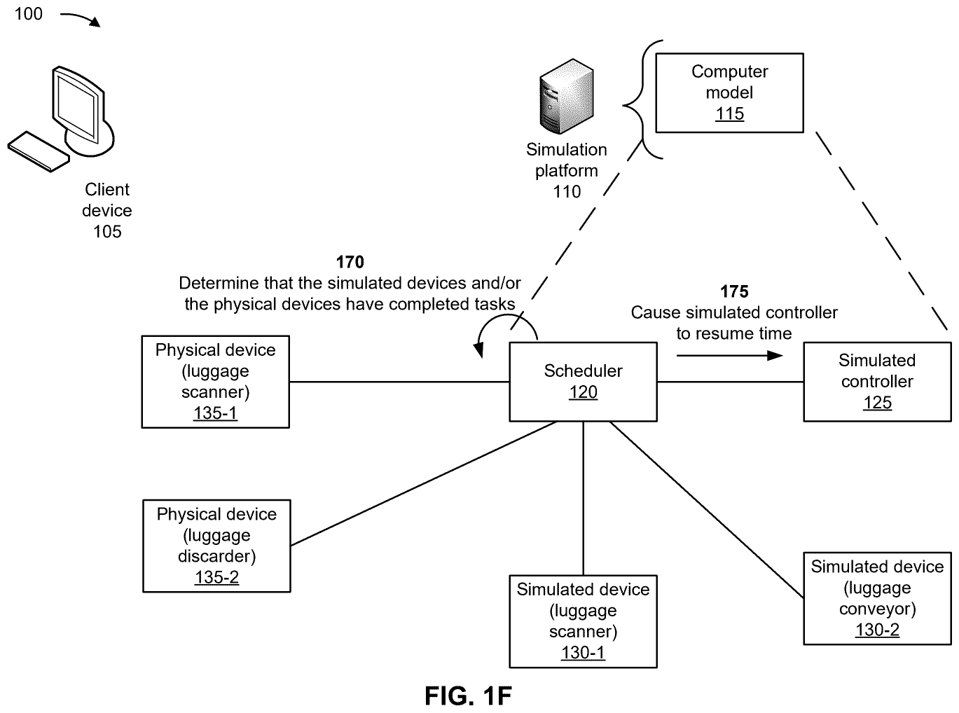

FIGS. 1A-1F are diagrams of an example implementation 100 associated with controlling elapsed time during a simulation. As shown in FIGS. 1A-1F, example implementation 100 includes a client device 105 and a simulation platform 110. The devices of FIGS. 1A-1F may be connected via a network that includes one or more wired and/or wireless networks. As an example, the network may include Ethernet switches. Additionally, or alternatively, the network may include a cellular network, a public land mobile network (PLMN), a local area network (LAN), a wide area network (WAN), a private network, the Internet, and/or a combination of these or other types of networks. The network enables communication between client device 105, simulation platform 110, and/or other devices (not shown).

Client device 105 may include one or more devices capable of receiving, generating, storing, processing, and/or providing information associated with controlling time during a simulation. Client device 105 may include a communication device and a computing device. For example, client device 105 may include a wireless communication device, a mobile phone, a user equipment, a laptop computer, a tablet computer, a desktop computer, or a similar type of device.

Simulation platform 110 may include one or more devices configured to host a simulation environment. As shown in FIG. 1A, simulation platform 110 may include a computer model 115. Computer model 115 may include a computer program that is executed to a launch the simulation. For example, simulation platform 110 may be configured to execute computer model 115 to launch (or initialize) the simulation.

As shown in FIG. 1A, in some situations, executing computer model 115 may launch a scheduler 120, a simulated controller 125, first simulated device 130-1 to simulated device 130-N (collectively “simulated devices 130”). Scheduler 120, simulated controller 125, simulated devices 130 may be launched based on one or more portions of the computer program.

Scheduler 120 may be configured to monitor and control operations of simulated controller 125 and simulated devices 130. For example, scheduler 120 may be configured to control operations of simulated controller 125 based on feedback from simulated devices 130. For example, scheduler 120 may monitor simulated devices 130 to determine whether simulated devices 130 have completed tasks during a step of the simulation (e.g., determined whether simulation devices 130 have completed the mathematical operations that are to be performed). Based on determining whether simulated devices 130 have completed the tasks, scheduler 120 may cause simulated controller 125 to suspend simulated time.

Simulated controller 125 may be configured to simulate operations of a physical controller. In some examples, the physical controller may include a programmable logic controller (PLC). In some situations, the PLC may be referred to as a wayside ride control system (WRCS). For example, the physical controller may include an industrial controller.

Simulated devices 130 may be configured to simulate operations of devices (e.g., physical devices) of a real-world system, such as a luggage handling system. The devices of the luggage handling system may include one or more luggage scanners, one or more conveyors, one or more luggage discarders (that cause luggage to be removed from a transportation flow of luggage), among other examples. Simulated devices 130 may logically represent the devices of the real-world system and may be configured to simulate operations of the devices by performing mathematical computations.

In some implementations, a portion of simulated devices 130 may be implemented on a device separate from simulation platform 110. For example, a portion of simulated devices 130 may be implemented on client device 105. Additionally, or alternatively, a portion of simulated devices 130 may be implemented in a cloud computing environment.

As shown in FIG. 1A, example implementation 100 may include physical device 135-1 to physical device 135-N (collectively “physical device 135”). Physical devices 135 may be devices of the luggage handling system. In some situations, physical devices 135 may be connected to simulation platform 110 and may provide input to scheduler 120. In this regard, scheduler 120 may monitor physical devices 135 to determine whether physical devices 135 have completed tasks during a step of the simulation. Based on determining whether physical devices 135 have completed the tasks, scheduler 120 may cause simulated controller 125 to suspend simulated time.

As shown in FIG. 1B, and by reference number 140, simulation platform 110 may receive a request to perform a simulation. In some implementations, the request may be received from client device 105. As an example, the request may be a request to simulate the operations of the luggage handling system.

As shown in FIG. 1B, and by reference number 145, simulation platform 110 may execute computer model to initialize a simulation. In some implementations, based on receiving the request, simulation platform 110 may execute computer model 115 to initialize the simulation. Additionally, or alternatively, simulation platform 110 may execute computer model 115 to initialize the simulation independent of receiving the request. For example, simulation platform 110 may execute computer model 115 to initialize the simulation periodically.

As part of initializing the simulation, simulation platform 110 may cause scheduler 120, simulated controller 125, and simulated devices 130 to be launched. In some situations, if a portion of simulated devices 130 is hosted on one or more separate devices (separate from simulation platform 110), simulation platform 110 may provide instructions to the one or more separate devices to launch the portion of simulated devices 130. Additionally, or alternatively, simulation platform 110 may provide instructions to physical devices 135 to initialize physical devices 135.

As shown in FIG. 1B, simulated device 130-1 may simulate operations of a luggage scanner while simulated device 130-2 may simulate operations of a luggage conveyor. As further shown in FIG. 1B, physical device 135-1 may be a luggage scanner while physical device 135-2 may be a luggage discarder.

As shown in FIG. 1B, and by reference number 150, simulation platform 110 may determine whether the simulated devices and/or the physical devices have completed tasks. In some implementations, initializing the simulation, scheduler 120 may monitor operations of simulated devices 130 and/or of physical devices 135. For example, during a step of the simulation, scheduler 120 may monitor operations of simulated devices 130 and/or of physical devices 135 to determine whether simulated devices 130 and/or of physical devices 135 have completed a set of tasks that are to be performed during the step to enable the simulation to proceed to a subsequent step. In some examples, the set of tasks may include mathematical computations.

As shown in FIG. 1C, scheduler 120 may receive input from simulated devices 130 and/or from physical devices 135 indicating whether the set of tasks have been completed. For example, based on monitoring, scheduler 120 may determine that simulated device 130-1 is performing mathematical computations for luggage scanning. For instance, simulated device 130-1 may provide input indicating that the mathematical computations for luggage scanning are being performed (e.g., due to data regarding simulated luggage being complex and/or due to limited computing resources for the mathematical computations).

Based on monitoring, scheduler 120 may determine that simulated device 130-2 has completed mathematical computations for conveying luggage. For instance, simulated device 130-2 may provide input indicating that the mathematical computations for conveying luggage have been completed (e.g., due to the simulation not providing data regarding luggage to be conveyed).

Based on monitoring, scheduler 120 may determine that physical device 135-1 has completed a task for luggage scanning. In some situations, physical device 135 may provide an input regarding a completion of the task for luggage scanning without performing mathematical computations. Alternatively, physical device 135 may provide an input regarding the completion of the task for luggage scanning after performing mathematical computations. Scheduler 120 may determine that physical device 135-2 has completed a task for luggage discarding in the same manner.

As shown in FIG. 1D, and by reference number 155, simulation platform 110 may determine that the simulated devices and/or the physical devices have not completed tasks. For example, based on monitoring the operations of simulated devices 130 and/or of physical devices 135, scheduler 120 may determine that simulated devices 130 and/or of physical devices 135 have not all completed the set of tasks to be completed during the step of the simulation. For instance, based on determining that simulated device 130-1 is performing the mathematical computations for luggage scanning, scheduler 120 may determine that simulated devices 130 and/or physical devices 135 have not all completed the set of tasks.

As shown in FIG. 1D, and by reference number 160, simulation platform 110 may cause simulated controller 125 to suspend time. For example, based on determining that simulated devices 130 and/or of physical devices 135 have not all completed the set of tasks to be completed during the step of the simulation, scheduler 120 may cause simulated controller 125 to suspend time. In some implementations, simulation platform 110 may provide a command to simulated controller 125 to suspend time that is elapsed during the simulation. For example, simulated controller 125 may suspend a simulated clock of the simulation. In this regard, as a system clock of simulation platform 110 continues to elapse, the simulated clock of the simulation may be suspended.

As shown in FIG. 1E, and by reference number 165, simulation platform 110 may determine whether the simulated devices and/or the physical devices have completed tasks. In some implementations, after providing the first instruction, scheduler 120 may continue to monitor simulated devices 130 and/or physical devices 135. For example, after providing the first instruction, scheduler 120 may monitor operations of simulated devices 130 and/or of physical devices 135 as described herein.

As shown in FIG. 1E, based on monitoring the operations of simulated devices 130 and/or of physical devices 135, scheduler 120 may determine that simulated device 130-1 has completed the mathematical computations for luggage scanning. Scheduler 120 may determine that simulated device 130-1 has completed the mathematical computations for luggage scanning as described herein.

As shown in FIG. 1F, and by reference number 170, simulation platform 110 may determine that the simulated devices and/or the physical devices have completed tasks. For example, based on monitoring the operations of simulated devices 130 and/or of physical devices 135, scheduler 120 may determine that simulated devices 130 and/or of physical devices 135 have all completed the set of tasks to be completed during the step of the simulation. For instance, based on determining that simulated device 130-1 has completed the mathematical computations for luggage scanning, scheduler 120 may determine that simulated devices 130 and/or physical devices 135 have all completed the set of tasks.

As shown in FIG. 1F, and by reference number 175, simulation platform 110 may cause simulated controller 125 to resume time. For example, based on determining that simulated devices 130 and/or physical devices 135 have all completed the set of tasks to be completed during the step of the simulation, scheduler 120 may provide a command to simulated controller 125 to resume time that is elapsed during the simulation. Simulated controller 125 may resume time during the simulation. For example, simulated controller 125 may resume the simulated clock of the simulation. Accordingly, the simulation may progress to a next of the simulation.

Implementations described herein relate to a simulated controller (e.g., a simulated process industrial controller) receiving time synchronization from a process model (e.g., from one or more simulated devices). In this regard, implementations described herein address issues related to a simulated device being unable to logically represent a physical device in real-time. Implementations described herein provide time synchronization ownership to the simulated devices. One or more system controllers could be clients of time synchronization sourced from the simulated devices. One or more additional simulated devices could be clients of time synchronization sourced from the simulated devices. Time offset may not impact system execution due to system time being sourced from the simulated devices, allowing the process being simulated to logically represent the physical system.

As indicated above, FIGS. 1A-1F are provided as an example. Other examples may differ from what is described with regard to FIGS. 1A-1F. The number and arrangement of devices shown in FIGS. 1A-1F are provided as an example. In practice, there may be additional devices, fewer devices, different devices, or differently arranged devices than those shown in FIGS. 1A-1F. Furthermore, two or more devices shown in FIGS. 1A-1F may be implemented within a single device, or a single device shown in FIGS. 1A-1F may be implemented as multiple, distributed devices. Additionally, or alternatively, a set of devices (e.g., one or more devices) shown in FIGS. 1A-1F may perform one or more functions described as being performed by another set of devices shown in FIGS. 1A-1F.

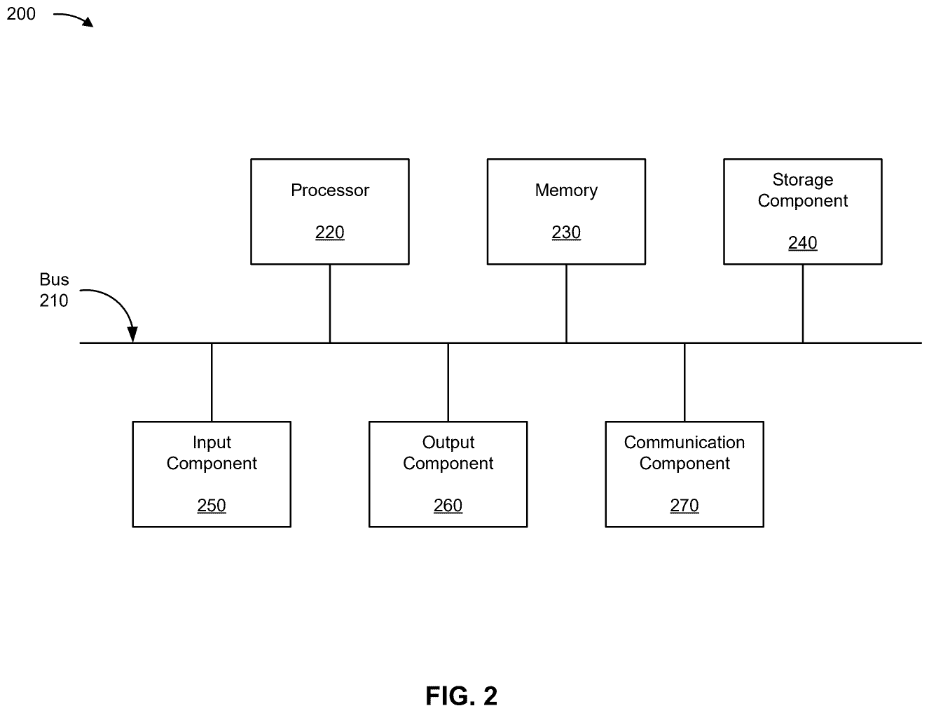

FIG. 2 is a diagram of example components of a device 200, which may correspond to client devices 105 and/or simulation platform 110. In some implementations, client devices 105 and/or simulation platform 110 may include one or more devices 200 and/or one or more components of device 200. As shown in FIG. 2, device 200 may include a bus 210, a processor 220, a memory 230, a storage component 240, an input component 250, an output component 260, and a communication component 270.

Bus 210 includes a component that enables wired and/or wireless communication among the components of device 200. Processor 220 includes a central processing unit, a graphics processing unit, a microprocessor, a controller, a microcontroller, a digital signal processor, a field-programmable gate array, an application-specific integrated circuit, and/or another type of processing component. Processor 220 is implemented in hardware, firmware, or a combination of hardware and software. In some implementations, processor 220 includes one or more processors capable of being programmed to perform a function. Memory 230 includes a random access memory, a read only memory, and/or another type of memory (e.g., a flash memory, a magnetic memory, and/or an optical memory).

Storage component 240 stores information and/or software related to the operation of device 200. For example, storage component 240 may include a hard disk drive, a magnetic disk drive, an optical disk drive, a solid state disk drive, a compact disc, a digital versatile disc, and/or another type of non-transitory computer-readable medium. Input component 250 enables device 200 to receive input, such as guest input and/or sensed inputs. For example, input component 250 may include a touch screen, a keyboard, a keypad, a mouse, a button, a microphone, a switch, a sensor, a global positioning system component, an accelerometer, a gyroscope, and/or an actuator. Output component 260 enables device 200 to provide output, such as via a display, a speaker, and/or one or more light-emitting diodes. Communication component 270 enables device 200 to communicate with other devices, such as via a wired connection and/or a wireless connection. For example, communication component 270 may include a receiver, a transmitter, a transceiver, a modem, a network interface card, and/or an antenna.

Device 200 may perform one or more processes described herein. For example, a non-transitory computer-readable medium (e.g., memory 230 and/or storage component 240) may store a set of instructions (e.g., one or more instructions, code, software code, and/or program code) for execution by processor 220. Processor 220 may execute the set of instructions to perform one or more processes described herein. In some implementations, execution of the set of instructions, by one or more processors 220, causes the one or more processors 220 and/or the device 200 to perform one or more processes described herein. In some implementations, hardwired circuitry may be used instead of or in combination with the instructions to perform one or more processes described herein. Thus, implementations described herein are not limited to any specific combination of hardware circuitry and software.

The number and arrangement of components shown in FIG. 2 are provided as an example. Device 200 may include additional components, fewer components, different components, or differently arranged components than those shown in FIG. 2. Additionally, or alternatively, a set of components (e.g., one or more components) of device 200 may perform one or more functions described as being performed by another set of components of device 200.

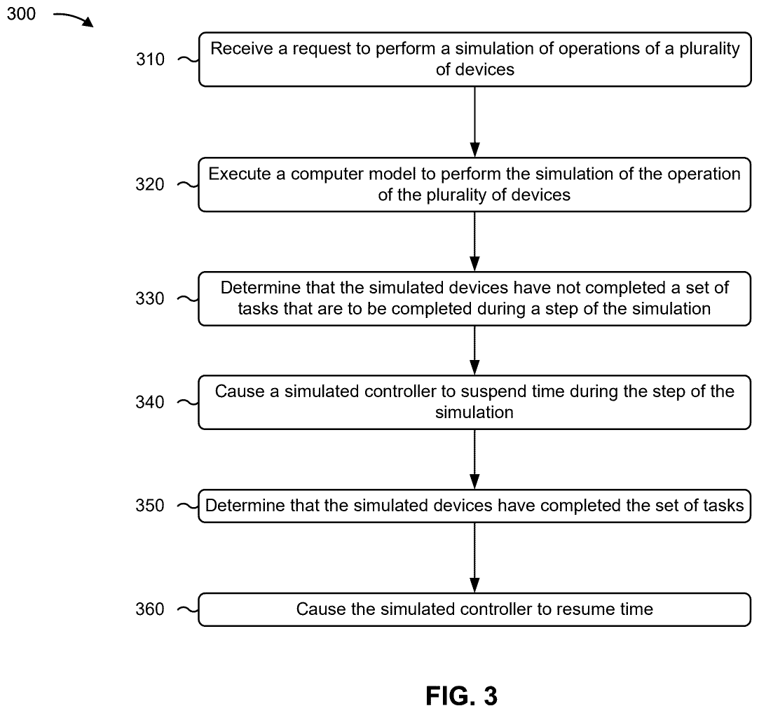

FIG. 3 is a flowchart of an example process 300 relating to controlling time during a simulation. In some implementations, one or more process blocks of FIG. 3 may be performed by a simulation platform (e.g., simulation platform 110). In some implementations, one or more process blocks of FIG. 3 may be performed by another device or a group of devices separate from or including the prediction platform, such as a client device (e.g., client device 105). Additionally, or alternatively, one or more process blocks of FIG. 3 may be performed by one or more components of device 200, such as processor 220, memory 230, storage component 240, input component 250, output component 260, and/or communication component 270.

As shown in FIG. 3, process 300 may include receiving a request to perform a simulation of operations of a plurality of devices (block 310). For example, the simulation platform may receive a request to perform a simulation of operations of a plurality of devices of a real-world system. The plurality of devices may include one or more sensor devices, motors, pumps, encoders, lights, projectors, doors, consoles, buttons of a console, controllers, devices that perform operations relating to physical motion, among other examples. In some examples, the plurality of devices may include a set of devices including one or more physical devices and one or more simulated devices.

As further shown in FIG. 3, process 300 may include execute a computer model to perform the simulation of the operation of the plurality of devices (block 320). For example, the simulation platform may execute the computer model (in the form of a computer program) to perform the simulation. Based on executing the computer program, a scheduler, a simulated controller, and simulated devices may be launched. The simulated devices may provide (e.g., via the scheduler) input to the simulated controller and the simulated controller may generate outputs to the simulation.

As further shown in FIG. 3, process 300 may include determining that the simulated devices have not completed a set of tasks that are to be completed during a step of the simulation (block 330). For example, the simulation platform may determine that one or more first simulated devices have completed mathematical computations to be performed during the step and determine one or more second simulated devices have not completed mathematical computations to be performed during the step. Accordingly, the simulation platform may determine that the simulated devices have not all completed the set of tasks.

As further shown in FIG. 3, process 300 may include causing the simulated controller to suspend time during the step of the simulation (block 340). For example, the simulation platform may prevent the simulated controller from advancing time until the simulated devices have all completed the set of tasks for the step. In some examples, determining that the simulated devices and/or the physical devices have not completed a set of tasks may be an event. In this regard, the simulated controller may be prevented from advancing time based on the event. In other words, time management may be managed by an event within the simulated controller. Time elapsed in the simulation may be different than time elapsed in a real-world environment.

As further shown in FIG. 3, process 300 may include determining that the simulated devices have completed the set of tasks (block 350). For example, after providing the first instruction, the simulation platform may continue to monitor the simulated devices. Based on monitoring the simulated devices, the simulated platform may determine that the simulated devices have completed the set of tasks.

As further shown in FIG. 3, process 300 may include providing a second instruction to resume time (block 360). For example, based on determining that the simulated devices have completed the set of tasks, the simulated platform may cause the simulated controller to resume time during the simulation. In some examples, determining that the simulated devices and/or the physical devices have completed the set of tasks may be an event. In this regard, the simulated controller may resume advancing time based on the event. In other words, time management may be managed by an event within the simulated controller.

Although FIG. 3 shows example blocks of process 300, in some implementations, process 300 may include additional blocks, fewer blocks, different blocks, or differently arranged blocks than those depicted in FIG. 3. Additionally, or alternatively, two or more of the blocks of process 300 may be performed in parallel.

In some implementations, a non-transitory computer-readable medium storing a set of instructions, the set of instructions comprising: one or more instructions that, when executed by one or more processors of a device, cause the device to: execute a computer model to cause a set of devices to perform different sets of tasks during different steps of a simulation to simulate operations of the set of devices; determine, during a step of the simulation, that the set of devices have not completed a set of tasks that are to be completed during a step of the simulation; provide, to a simulated controller, a first instruction to suspend time elapsed during the simulation based on determining that the simulated devices have not completed the set of tasks; determine, during the step of the simulation, that the simulated devices have completed the set of tasks after providing the first instruction; and provide, to the simulated controller, a second instruction to resume time based on determining that the simulated devices have performed the set of tasks.

The foregoing disclosure provides illustration and description, but is not intended to be exhaustive or to limit the implementations to the precise forms disclosed. Modifications may be made in light of the above disclosure or may be acquired from practice of the implementations.

As used herein, satisfying a threshold may, depending on the context, refer to a value being greater than the threshold, greater than or equal to the threshold, less than the threshold, less than or equal to the threshold, equal to the threshold, not equal to the threshold, or the like.

As used herein, the term “component” is intended to be broadly construed as hardware, firmware, or a combination of hardware and software. It will be apparent that systems and/or methods described herein may be implemented in different forms of hardware, firmware, and/or a combination of hardware and software. The actual specialized control hardware or software code used to implement these systems and/or methods is not limiting of the implementations. Thus, the operation and behavior of the systems and/or methods are described herein without reference to specific software code-it being understood that software and hardware can be used to implement the systems and/or methods based on the description herein.

Although particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A method performed by a scheduler of a simulation platform, the method comprising:
receiving a request to perform a simulation of operations of a plurality of devices;
executing, based on the request, a computer model to perform the simulation of the operations of the plurality of devices,
executing the computer model includes causing simulated devices, representing the plurality of devices, to perform different sets of tasks during different steps of the simulation to simulate the operations of the plurality of devices;
determining, during a step of the simulation, that the simulated devices have not completed a set of tasks that are to be completed during the step of the simulation;
causing a simulated controller associated with the simulation to suspend time during the step of the simulation based on determining that the simulated devices have not performed a set of tasks;
determining, during the step of the simulation, that the simulated devices have completed the set of tasks after causing the simulated controller to suspend time; and
causing the simulated controller to resume time based on determining that the simulated devices have performed the set of tasks.

2. The method of claim 1, wherein determining that the simulated devices have not performed the set of tasks comprises:
determining that a first simulated device has performed a first task during the step of the simulation;
determining that a second simulated device has not performed a second task during the step of the simulation; and
determining that the simulated devices have not performed the set of tasks based on determining that the second simulated device has not performed the second task during the step of the simulation.

3. The method of claim 2, wherein causing the simulated controller to suspend time comprises:
causing the simulated controller to suspend time based on determining that the second simulated device has not performed the second task during the step of the simulation.

4. The method of claim 1, wherein time elapsed in the simulation is different than time elapsed in a real-world environment, and
wherein the set of tasks include a set of mathematical computations.

5. The method of claim 1, wherein causing the simulated controller to resume time comprises:
causing the simulated controller to advance time independent of a clock of a device associated with the simulation platform.

6. The method of claim 1, wherein the plurality of devices include machines that perform operations relating to physical motion.

7. The method of claim 1, wherein the simulated devices include models of the plurality of devices.

8. A system, comprising:
a simulated controller to control elapsed time during simulations; and
a simulation platform to:
execute a computer model to cause a set of devices to perform different sets of tasks during different steps, of a simulation, to simulate operations of the set of devices,
the set of devices including one or more physical devices and one or more simulated devices;
determine, during a step of the simulation, that the set of devices have not completed a set of tasks that are to be completed;
cause the simulated controller to suspend time elapsed during the simulation based on determining that the set of devices have not performed the set of tasks;
determine, during the step of the simulation, that the set of devices have completed the set of tasks after causing the simulated controller to suspend time elapsed during the simulation; and
cause the simulated controller to resume time based on determining that the set of devices have completed the set of tasks.

9. The system of claim 8, wherein time elapsed in the simulation is different than time elapsed in a real world environment.

10. The system of claim 8, wherein, to cause the simulated controller to resume time, the simulation platform is to:
cause the simulated controller to advance time independent of a clock of a device associated with the controller.

11. The system of claim 8, wherein the set of devices include devices that perform operations relating to physical motion.

12. The system of claim 8, wherein the one or more physical devices include one or more first physical devices, and
wherein the one or more simulated devices include models of one or more second physical devices.

13. The system of claim 8, wherein, to determine that the set of devices have not completed the set of tasks, the simulation platform is to:
determine that a physical device has completed a first task during the step of the simulation;
determine that a simulated device has not completed a second task during the step of the simulation; and
determine that the set of devices have not completed the set of tasks based on determining that the simulated device has not completed the second task during the step of the simulation.

14. The system of claim 13, wherein, to cause the simulated controller to suspend time, the simulation platform is to:
cause the simulated controller to suspend time based on determining that the simulated device has not completed the second task during the step of the simulation.

15. A device, comprising:
one or more processors configured to:
execute a computer model to cause a set of devices to perform different sets of tasks during different steps of a simulation to simulate operations of the set of devices;
determine, during a step of the simulation, that the set of devices have not completed a set of tasks that are to be completed during a step of the simulation;
cause a simulated controller to suspend time elapsed during the simulation based on determining that the set of devices have not completed the set of tasks;
determine, during the step of the simulation, that the set of devices have completed the set of tasks after causing the simulated controller to suspend time; and
cause the simulated controller to resume time based on determining that the simulated devices have performed the set of tasks.

16. The device of claim 15, wherein, to cause the simulated controller to resume time, the one or more processors are further configured to:
cause the simulated controller to advance time independent of a clock of a device associated with the simulated controller.

17. The device of claim 15, wherein time elapsed in the simulation is different than time elapsed in a real-world environment.

18. The device of claim 15, wherein the set of devices include at least one of:
one or more physical devices, or
one or more simulated devices.

19. The device of claim 18, wherein the one or more physical devices include one or more first physical devices, and
wherein the one or more simulated devices include models of one or more second physical devices.

20. The device of claim 15, wherein, to determine that the set of devices have not completed the set of tasks, the one or more processors are further configured to:
determine that a physical device has completed a first task during the step of the simulation;
determine that a simulated device has not completed a second task during the step of the simulation; and
determine that the set of devices have not completed the set of tasks based on determining that the simulated device has not completed the second task during the step of the simulation.
